(19) United States
(12) Patent Application Publication
(10) Pub. No.: US 2002/0094702 A1
(43) Pub. Date: Jul. 18, 2002

(54) Mounting adapter for use with a voltage regulator tap position indicator

(76) Inventor: Joshua J. Herz, Rochester, NY (US)

Correspondence Address: Stephen B. Salai, Esq., Harter, Secrest & Emery LLP, 1600 Bausch & Lomb Place, Rochester, NY, 14604-2711, US

(21) Appl. No.: 09/764,666

(22) Filed: Jan. 18, 2001

(51) Int. Cl. H05K 1/00

(52) U.S. Cl. 439/55

(57) ABSTRACT

Disclosed is an adapter for communicating the turning output of a voltage regulator tap change mechanism to a tap position indicator. The adapter has a receptor that axially receives the turning output of the change mechanism and includes an intermediate gear that meshes with the input to the position indicator. This reverses the turning direction of the change mechanism output as applied to the position indicator. The adapter and position indicator have cooperating nesting members that align the adapter and position indicator to accomplished the meshing of the intermediate gear with the input to the position indicator.

### TECHNICAL FIELD

The present invention relates generally to means for registering the tap position of a voltage regulator and more particularly to an adapter for communicating the output of a tap change mechanism to the input of a tap position indicator.

### BACKGROUND OF THE INVENTION

The use of voltage regulators to provide constant voltage on an electrical power distribution system is known in the art. As the load on the electrical system changes, a change mechanism within the voltage regulator seeks to maintain a constant voltage by automatically stepping from one transformer tap to another. As the mechanism steps from one tap to another, the new position is registered on a position indicator mounted to the exterior of the voltage regulator. The position indicator usually is in the form of a dial face with a single indicator hand that points to the current position of the change mechanism.

It is customary for the change mechanism to include a flexible shaft. As the mechanism steps from one tap to another, the flexible shaft turns in one direction or another depending upon whether the stepping is to a higher or lower tap. The turning of the flexible shaft is used to drive the indicator hand through a system of gears within the position indicator.

There are two popular styles of change mechanisms. These two styles employ opposite conventions with respect to the direction that the flexible shaft turns in response to a tap change. Consequently, two types of position indicators have been developed dedicated exclusively to one or the other of these two styles of change mechanisms.

Both types of position indicators employ a common convention with respect to the movement of the indicator hand so that in each, the indicator hand moves in the same direction to indicate a tap change. However, each type of position indictor employs a gear system designed to accommodate the flexible shaft convention of one or the other of the popular styles of change mechanisms. For example, in a first common type of position indicator (hereinafter “Type A”) the gear system is arranged to move the indicator hand in the same direction as the rotation of the flexible shaft. In this type, the gear system has an input gear that is connected directly to the flexible shaft and turns in the same direction as the shaft. In the second common type of position indicator (hereinafter “Type B”) the indicator hand is geared to move in a direction opposite to the rotation of the flexible shaft. Accordingly, a position indicator dedicated to one style of change mechanism is incompatible with a change mechanism having its flexible shaft rotating in an opposite convention.

Heretofore, the Type A position indicator has not been used as a direct replacement for the Type B position indicator. This is because the gear system of the Type A position indicator could not accommodate a flexible shaft that turns in a direction counter to the direction of the indicator hand. While modification of the gear system of the Type A position indicator is possible, such modification is an expensive proposition. For this reason there is a reluctance to change the gear system to make the Type A position indicator compatible with a change mechanism having a flexible shaft that turns in a direction opposite to the indicator hand.

Accordingly, an object of the present invention is to provide an adapter to compensate for an otherwise incompatible direction of rotation of the flexible shaft of a change mechanism used in a voltage regulator to maintain constant voltage.

Another object is to provide an adapter that permits the use of a Type A position indicator with a change mechanism having a flexible shaft that turns in a direction opposite to the direction of the indicator hand.

A further object of the present invention is to provide an adapter and position indicator having mating components that cooperate to interpose a rotation reversing gear assembly between the input gear of the position indicator and the flexible shaft of a change mechanism.

A still further object of the present invention is to provide an adapter including a rotation reversing gear assembly having an input end in mating axial alignment with the flexible shaft of a change mechanism.

### SUMMARY OF THE INVENTION

The present invention provides an adapter for use with a Type A position indicator. In particular, the adapter permits the use of the position indicator in association with a change mechanism having a flexible shaft that turns in the opposite direction as the indicator hand. The adapter and position indicator each have cooperating mating members that establish an alignment and operational engagement of components for reversing the direction of rotation of the flexible shaft.

In this respect, the position indicator has an outward extending bearing. Journaled to this bearing is a spur gear. The spur gear represents the input to the position indicator gear assembly in that the spur gear rotates in the same direction as the indicator hand. The adapter is attachable to the position indicator and includes a seat that has a snug fit with the bearing. Accordingly, the reception of the bearing into the seat establishes a defined positional relationship between the adapter and the position indicator.

Journaled to the adapter is a drive including an intermediate gear that meshes with the input spur gear when the bearing is received into the seat. The drive further includes a receptor for axially receiving and nesting a pinion at the end of the rotary shaft extending from a change mechanism. The engagement of receptor and pinion causes the intermediate gear and pinion to turn in the same direction and on the same axis. While the intermediate gear and pinion turn in concert, the meshing of the intermediate and spur gears cause the spur gear to turn in an opposite direction. This direction reversal renders the rotation of the flexible shaft compatible with a Type A position indictor having an indicator hand that turns in the same direction as the input to the position indicator gear assembly.

Accordingly, the present invention may be characterized in one aspect thereof by an adapter for connecting a pinion on the end of a change mechanism flexible shaft to the input gear of a position indicator for turning the input gear in a direction opposite to the direction of rotation of the pinion, the adapter comprising:

a) a plate attachable to the position indicator;

b) a receptor journaled to the plate for rotation about an axis extending generally normal to the plane of the plate, the receptor having a first end for axially receiving and nesting the pinion such that the pinion and receptor turn on a common axis and the receptor is driven by the pinion;

c) the plate having a first seat opening outward through one side of the plate for receiving a bearing extending from the position indicator wherein the reception of the bearing into the seat establishes a defined positional relationship between the position indicator and the plate that places the axis of the receptor parallel to and laterally spaced from the rotational axis of the position indicator input gear; and

d) an intermediate gear fixed to the receptor and adapted to mesh with the input gear of the position indicator when the bearing is seated in the seat whereby the turning of the receptor by the pinion causes the input gear to turn in a direction opposite to the pinion.

### DESCRIPTION OF THE DRAWINGS

FIG. 1 is a schematic view showing a voltage regulator and position indicator including an adapter according to the present invention;

FIG. 2 is an exploded perspective view partly broken away and in section showing an adapter and the rear side of a position indicator;

FIG. 3 is a sectional view of the adapter shown in FIG. 2;

FIGS. 4 and 5 are views of portions of FIGS. 2 and 3 respectively on an enlarged scale;

FIG. 6 is a view partly broken away and in section of an adapter according to the present invention attached to a tap position indicator; and

FIG. 7 is a cross sectional view taken along lines 7-7 of FIG. 6.

### DETAILED DESCRIPTION OF THE INVENTION

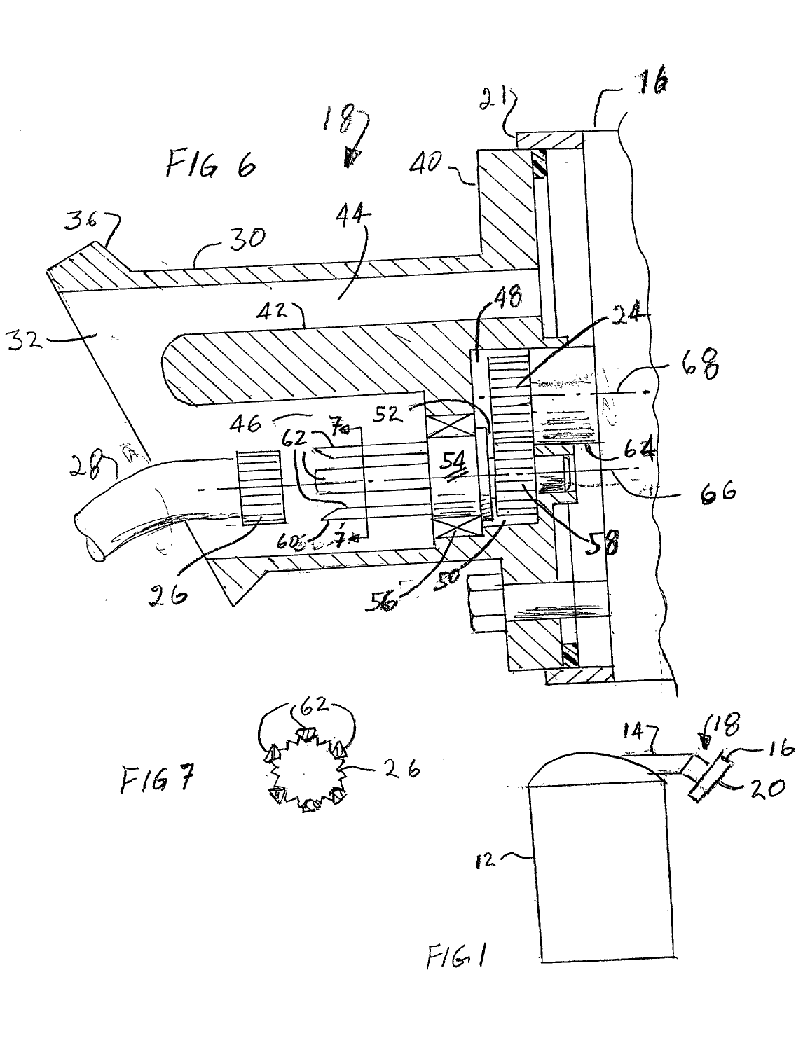

Referring to the drawings, FIG. 1 shows the exterior housing 12 of a voltage regulator. Within the housing are the transformer windings and a change mechanism that connects to one tap or another for maintaining constant voltage. The transformer and change mechanism are conventional and form no part of the present invention. Extending from the housing 12 is a duct 14. Various electrical cables and the flexible shaft of the change mechanism extend through this duct. A position indicator 16 at the outward end of the duct is mounted to the duct by means of an adapter generally indicated at 18. The adapter is arranged to angle a face 20 of the position indicator downwardly to facilitate viewing by an operator standing below the voltage regulator. The position indicator is conventional (except as noted below) and its face 20 includes a dial and an indicator hand (not shown) that points to the current transformer tap position.

Referring now to FIG. 2, the adapter 18 and its relationship to the position indicator 16 is shown in greater detail. For purposes of illustration, the position indicator is shown with its dial face 20 down and obscured to more clearly show the rear side 21 of the position indicator and its connection to the adapter 18.

Extending from the rear side of the position indicator is a shaft 22 (FIG. 4). The shaft 22 in turn is connected to a gear train (not shown) within the position indicator that is arranged to turn the indicator hand in the same direction as the shaft. The shaft 22 may be considered the input of the position indicator. The type of position indicator shown is intended for use with a change mechanism having a flexible shaft that turns in the same direction as shaft 22. Accordingly, the flexible shaft of the change mechanism can be coupled directly to the shaft 22 so the flexible shaft and shaft 22 turn in concert. However, such a direct connection is not acceptable in cases where the flexible shaft turns in an opposite direction. Accordingly, the adapter of the present invention allows for the use of a Type A position indicator with such a change mechanism (i.e. one having a flexible shaft 28 that terminates in a pinion 26, which turns in an opposite direction).

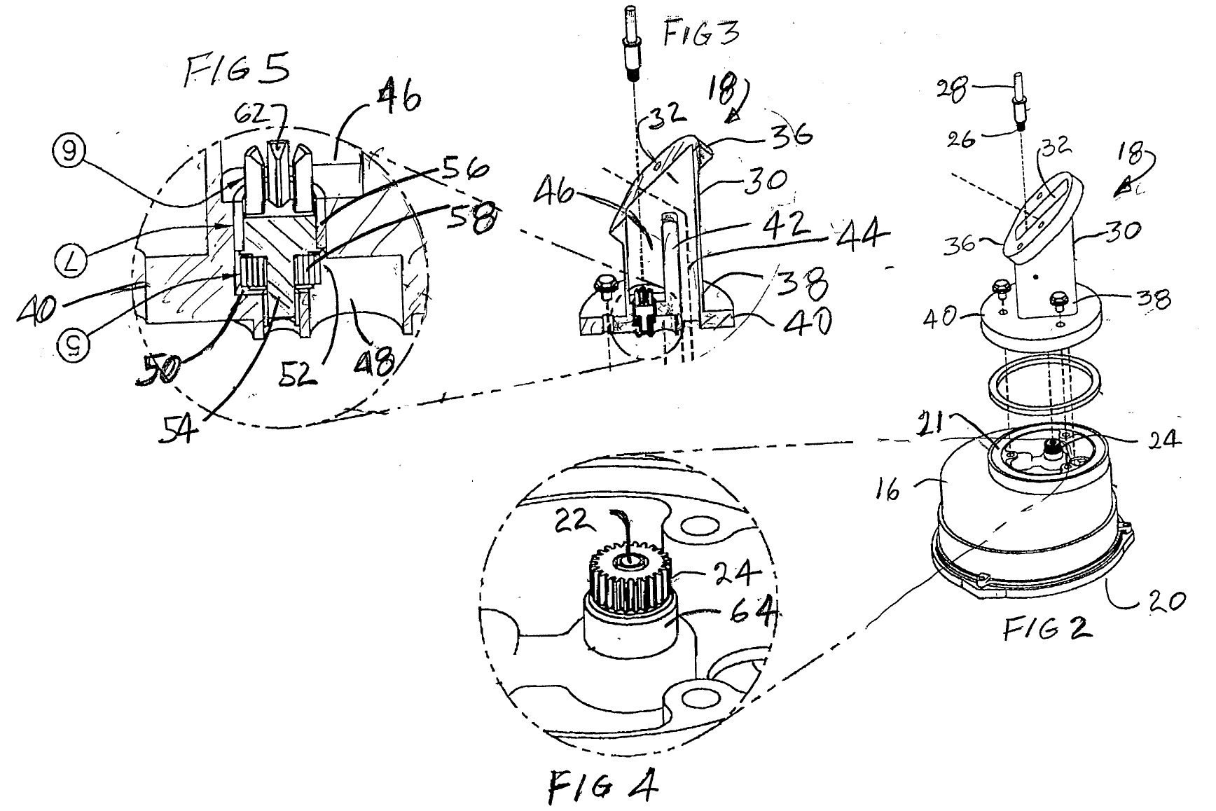

Referring now to FIGS. 2 and 3, the adapter 18 is shown to include a hollow housing 30 that is generally rectangular in cross section. A first end 32 of the housing is open and is disposed at an angle with respect to the longitudinal axis of the housing. A flange 36 at the open end provides the means for attaching the adapter to the duct 14 (FIG. 1).

Formed integral a second end 38 of housing is a mounting plate 40 that is disposed generally normal to the longitudinal axis of the housing. The mounting plate 40 includes the means for attaching the adapter to the rear side 21 of the position indicator 16.

The housing 30 includes an internal wall 42 (FIG. 3) that longitudinally partitions the interior of the housing. In this respect, the internal wall 42 defines a passage 44 extending through both the housing and the mounting plate to accommodate any wires or other electrical connections (not shown) that may pass between the interior of the position indicator 16 and the interior of the transformer housing 12. The internal wall also defines an open ended chamber 46 within the hollow housing 30. The open end of the chamber opens through the open end 32 of the housing. The opposite end of the chamber is closed and is defined by the mounting plate 40.

Formed in the mounting plate 40 by precision machining are first and second seats 48,50 respectively. As best seen in FIGS. 5 and 6, the first seat 48 opens outward from the mounting plate whereas the second seat 50 opens into the chamber 46. The positioning of the two seats is such that there is a slight overlap so that an opening 52 is formed between the two seats.

Disposed in the second seat 50 is a shaft 54. The shaft is journaled in the second seat and is held in the seat by a bearing 56. A spur gear 58, referred to hereafter as an intermediate gear, is press fit to the shaft adjacent one end so that the outer periphery of the intermediate gear rotates through the opening 52 and into the first seat 48. The opposite end 60 of the shaft is larger in diameter than the first end. The larger shaft end 60 extends through the bearing 56 and into the chamber 46. The end 60 of the shaft is bored and slotted to form a plurality circumferentially spaced longitudinally extending keys 62. These keys define a receptor adapted to mesh and engage about the periphery of the pinion 26 as shown in FIG. 7.

The first seat 48 of the mounting adapter is sized to receive the input spur gear 24 of the position indicator. Moreover, as best seen in FIG. 4, the shaft 22 mounting the input spur gear 24 extends through a bearing 64 wherein the outside diameter of bearing 64 is machined to fit snugly into the first seat 48 for purposes set out hereinbelow.

FIG. 6 shows the adapter 18 attached to the position indicator 16. In this respect, the mounting plate 40 is placed flush on the rear side 21 of the position indicator with the bearing 64 received into the seat 48. The reception of bearing 64 into the seat 48 establishes a defined relationship between the position indicator 16 and the mounting plate 40 that places the axis 66 of the shaft 54 parallel to and laterally off set from the axis 68 of the input gear 24. This arrangement allows input spur gear 24 to mesh with the periphery of the intermediate gear 58 that turns through the opening 52 and into the seat 48.

The flexible shaft 28 of the change mechanism then is led through the housing open end 32 and into the chamber 46. The pinion 26 on the end of this shaft is axially received into the receptor defined by the keys 62. Any suitable means, such as a setscrew (not shown) in the side of the housing may be used to prevent the pinion from pulling out from between the keys 62.

As best seen in FIG. 7, the pinion 26 is nested between the keys 62 and is held by the keys so that the pinion 26 is axially aligned with the shaft 54 and is coupled directly to the shaft. As the pinion 26 turns, this movement is transmitted to the shaft 54 and to the intermediate gear 58 fixed to this shaft. The gear 58, in turn, is meshed with the input spur gear 24 so by interposing the intermediate gear 58 between the pinion 26 and input spur gear 24, the input spur gear 24 and shaft 22 turn in a direction opposite to the pinion 26.

Thus, the adapter of the present invention allows a Type A position indicator (indicator hand turns in the same direction as the flexible shat) to replace a Type B position indicator by attaching to a flexible shaft having a contrary rotation convention. Moreover, the adapter 16 provides in one integral structure, an intermediate gear to reverse the direction of rotation, means to axially couple the pinion of the flexible shaft to the intermediate gear and the means to properly align the intermediate gear with the input spur gear of the position indicator. Also, part of the integral structure is a passage 44 to accommodate wires that may pass between the change mechanism and the position indicator.

Thus, it should be appreciated that the present invention accomplishes its intended objects in providing an adapter for mating a voltage regulator change mechanism to a position indicator. The adapter effectively reverses the turning direction of the pinion at the end of the change mechanism flexible shaft so the Type A position indicator can be used with a flexible shaft that turns in a contrary direction.

The adapter has input and output ends that mate respectively with the pinion of the change mechanism and the input spur gear of the position indicator. A gear intermediate these ends effects the change of the direction of rotation needed to mate the output of the change mechanism to the position indicator. Moreover, the input end of the adapter includes a receptor that axially aligns with the pinion of the change mechanism to facilitate the connection of one to the other.

Having described the invention in detail, what is claimed as new is:

1. A adapter for connecting a pinion on the end of change mechanism flexible shaft to the input gear of a position indicator for turning the input gear in a direction opposite to the direction of rotation of the pinion, said adapter comprising:
a) a hollow housing providing a passage for electrical connections extending between the change mechanism and the position indicator;
b) a plate formed integral a first end of said housing, said plate being attachable to the position indicator;
c) a receptor journaled to said plate for rotation about an axis extending generally normal to the plane of said plate, said receptor having a first end extending into said housing for axially receiving and nesting the pinion such that the pinion and receptor turn on a common axis and said receptor is driven by the pinion;
d) said plate having a first seat opening outward through one side of said plate and away from said housing for receiving a bearing extending from the position indicator wherein the reception of the bearing into said seat establishes a defined positional relationship between the position indicator and said housing that places the axis of said receptor parallel to and laterally spaced from the turning axis of the position indicator input gear; and
e) an intermediate gear fixed to said receptor and adapted to mesh with the input gear of the position indicator when said bearing is seated in said seat whereby the turning of said receptor by said pinion causes said input gear to turn in a direction opposite to the pinion.

2. An adapter as in claim 1 wherein said receptor comprises:
a) a shaft journaled to said plate; and
b) a plurality of spaced keys disposed about the periphery of said shaft and extending longitudinally from a first end of said shaft, said keys defining a nest for axially receiving the pinion and being rotatably engaged by the pinion.

3. An adapter as in claim 1 wherein said input gear is journaled to said bearing and turns within said first seat.

4. An adapter as in claim 3 wherein said plate has a second seat opening outward through an opposite side of said plate and into said housing, said intermediate gear being rotatably retained in said second seat.

5. An adapter as in claim 4 wherein said first and second seats partly over lap to provide an opening between said seats, said intermediate gear having its outer periphery rotating through said opening and into said first seat to engage said input gear.

6. An adapter as in claim 1 wherein:
a) said plate is disposed generally normal to a longitudinal axis of said housing and closes said first end;
b) said plate having an opening for passing said electrical connectors from said housing, a second end of said housing being open; and
c) a flange about said second end for attaching said housing to a component of the change mechanism.

7. An adapter as set forth in claim 6 wherein said housing has an internal wall that longitudinally partitions said hollow housing into two portions, one of said portions accommodating the electrical connectors and a second of said portions receiving the flexible shaft for connecting the pinion to said receptor.

8. In combination, an adapter connected between a position indicator and a flexible shaft of a change mechanism, comprising:
a) a position indicator having a dial face with an indicator hand and a rear face, a bearing extending from said rear face and an input gear journaled to said bearing, said input gear adapted to turn in the same direction as the indicator hand;
b) a change mechanism including a flexible shaft and a pinion at the end of said shaft adapted to turn in a direction opposite to said indicator hand;
c) an adapter including a hollow housing having a closed end formed by a plate extending normal to a longitudinal axis of said housing and an open end, said plate being attachable to said position indicator rear face;
d) an internal wall extending into said housing from said plate, said internal wall dividing said housing into first and second longitudinal portions, said first portion defining a passage for electrical connectors that extend between said change mechanism and said position indicator and a second of said portions receiving said flexible shaft;
e) a receptor journaled to said plate and extending into said second longitudinal portion, said receptor including means for axially connecting to said pinion wherein said intermediate gear is driven by said pinion about a common turning axis;
f) an intermediate gear fixed to said receptor and meshed with said input gear for turning said input gear in a direction opposite to said pinion; and
g) said plate having a first seat opening from said plate and away from said housing for receiving said bearing wherein the reception of said bearing into said seat establishes a defined positional relationship between said position indicator and said housing that places the rotational axis of said receptor and intermediate gear parallel to and laterally offset from the rotational axis of said input gear to accomplish the meshing of said intermediate and input gears.

9. A combination as in claim 8 wherein said receptor comprises:
a) a shaft journaled to said plate;
b) a plurality of keys extending longitudinally from about the periphery of a first end of said shaft, said keys being circumferentially spaced to form a nest for axially receiving said pinion in a driving relationship such that said pinion turns said shaft in the same direction; and
c) said intermediate gear being fixed to said shaft.

10. A combination as in claim 9 wherein:
a) said plate has a second seat opening into the second longitudinal portion of said housing to rotatably house said intermediate gear; and
b) said first and second seats overlapping to provide an opening from one seat to the other whereby said intermediate gear turns through said opening to mesh with said input gear in said first seat.

11. A combination as in claim 8 including a flange about said open end for connecting said adapter to said change mechanism.
